(19) United States
(12) Patent Application Publication
(10) Pub. No.: US 2017/0223879 A1
(43) Pub. Date: Aug. 3, 2017

(54) LABEL ARRANGEMENT AND AN ITEM COMPRISING SAID LABEL ARRANGEMENT

(71) Applicant: UPM Raflatac Oy, Tampere (FI)

(72) Inventors: Noel Mitchell, Wuppertal (DE); Klaudia Korman, Bielany Wroclawskie (PL)

(21) Appl. No.: 15/008,549

(22) Filed: Jan. 28, 2016

(51) Int. Cl. H05K 9/00; G09F 3/10; G09F 3/00; B65D 85/80; B65D 25/20

(52) U.S. Cl. CPC H05K 9/0088; H05K 9/0094; B65D 85/80; B65D 25/205; G09F 3/0291; G09F 3/10; G09F 2003/0216

(57) ABSTRACT

The invention relates to an electromagnetic radiation blocking label arrangement and to a labelled item comprising said label arrangement. According to an embodiment the label arrangement comprises at least one label component including a shrinkable film and at least one metal deposition layer on a surface of the shrinkable film. The shrinkable film is uniaxially stretched so as to form shrinking capability for the film when exposed to an external energy.

### TECHNICAL FIELD

The application relates to an electromagnetic radiation blocking label arrangement. Especially to a label arrangement comprising shrinkable label(s), which are blocking electromagnetic radiation, such as light blocking shrinkable labels used for labelling of plastic milk bottles. Further the application concerns labelled items, such as PET bottles.

### BACKGROUND

The use of polymer containers, for example bottles made of thermoplastic polymers, has been increasing. In order to provide decoration, identification and/or information, for example, on the contents of the container, it is general practice to apply a label to the surface of container. In an environmental point of view, recycling of the containers, such as plastic bottles made of PET, is an increasingly important aspect. In order to provide efficient and cost effective recycling, requirements for both containers and labels exist. In an example, it would be desirable that the labels are removable from the surface of the container but also separable in the normal sink-float washing process thus promoting recycling of the container.

### SUMMARY

It is an aim to provide a label arrangement suitable for blocking electromagnetic radiation. It is a further aim to provide a labelled container suitable for providing extended shelf life for the product to be packaged into the container. It is also an aim to provide a label arrangement, which is removable from the surface of the item labelled in a subsequent recycling process.

According to an embodiment an electromagnetic radiation blocking label arrangement is provided. The label arrangement comprises at least one label component including: a shrinkable film and at least one metal deposition layer on a surface of the shrinkable film. In order to form shrinking capability for the shrinkable film, the film is uniaxially stretched.

According to an embodiment an electromagnetic radiation blocking label arrangement is used for labelling of a foodstuff container, such as a container for packaging of dairy products, for example labelling of UHT milk bottles.

According to an embodiment a labelled item comprising an electromagnetic radiation blocking label arrangement is provided. The labelled item comprises the at least one label component shrunk around the item.

Further embodiments of the application are presented in dependent claims.

In an example, the shrinkable film comprises: propylene terpolymer or propylene random copolymer and at least one of the following modifiers: polyolefin elastomer, polyolefin plastomer and olefin block copolymer.

In an example, the metal deposition layer comprises at least one of the following: aluminium, chromium and nickel. The metal deposition layer may consist of aluminium. The metal deposition layer may have thickness between 30 and 500 Å.

In an example, the shrinkable film comprises layers in the following order: a first skin layer, a core layer, and a second skin layer and wherein the metal deposition layer is underlying the second skin layer.

In an example, the core layer comprises light blocking agent or pigment between 0.1 and 30 wt. %.

In an example, the at least one label component exhibits density between 0.85 and 0.98 g/cm³ at room temperature (23±2° C.).

In an example, the at least one label component exhibits an opacity between 70 and 95%, when measured according to standard ISO 2471.

In an example, the at least one label component exhibits a light transmittance between 0 and 20% at wavelengths between 200 and 650 nm.

In an example, the at least one label component exhibits an optical density between 1.0 and 3.5 at wavelength of 530 nm.

In an example, the at least one label component exhibits at least 15% shrinkage in the uniaxial stretching direction between temperature of 65 and 98° C.

In an example, the label arrangement further comprises a second label component, wherein the second label component is self-adhesive label or shrink label.

In an example, the labelled item comprises the second label component arranged onto the bottom of the item or around the neck of the item.

In an example, the labelled item is clear polyethylene terephthalate container.

In an example, the labelled item is a bottle for packaging of dairy product or wherein the labelled item includes dairy product.

In an example, the item is a bottle for packaging of UHT milk or wherein the labelled item includes UHT milk.

In an example, the label arrangement covers at least 90% of the outer surface of the labelled item.

### BRIEF DESCRIPTION OF THE DRAWINGS

In the following some examples and embodiments will be described in more detail with reference to appended drawings, in which,

FIG. 1 shows, in a perspective view, an example of heat shrinking of a shrinkable film and a shrunk film,

FIG. 2 shows, in a perspective view, an example of a multilayer shrinkable film for a label,

FIG. 3 shows, in a perspective view, an example of an electromagnetic radiation blocking shrinkable film for a label,

FIG. 4 shows an example of a shrinkable label around an article (before shrinking),

FIG. 5 shows an example of a labelled article comprising a shrunk label (after shrinking),

FIG. 6 shows an example of a shrinkable label around an article and a labelled article comprising a shrunk label (after shrinking),

FIG. 7 shows an example of a shrinkable label around an article and a labelled article comprising a shrunk label (after shrinking),

FIG. 8 shows, in a cross-sectional view, an example embodiment of a seamed shrink label,

FIGS. 9A, 9B show an example of a method for seaming of a shrink film so as to provide a shrink label,

FIG. 10 shows labelling of articles with shrink sleeve labels.

### DETAILED DESCRIPTION

In this description and claims, the percentage values relating to an amount of raw materials are percentages by weight (wt. %) unless otherwise indicated, e.g. percentages by weight of the total weight of the plastic film. Word “comprising” may be used as an open term, but it also comprises the closed term “consisting of”. Unit of thickness expressed as microns corresponds to μm. Unit of temperature expressed as degrees C. corresponds to ° C. The following reference numbers and denotations are used in this application:

Sx, Sy, Sz 3D coordinates,

TD transverse direction,

CD cross direction,

MD machine direction,

DR draw ratio (stretching ratio)

MRK1 graphics (printing, print layer),

L1 length of a label film prior to shrinking,

w1 width of a label film prior to shrinking,

d1 thickness of a label film prior to shrinking,

L2 length of a shrunk label film,

w2 width of a shrunk label film,

d2 thickness of a shrunk label film,

1 a shrinkable film,

3 a multilayer film

2 a first skin layer,

5 an electromagnetic radiation blocking shrinkable film

4 a core layer,

6 a second skin layer,

7 a metal deposited layer (metallization layer),

8 a first longitudinal edge of a shrinkable film,

10 a shrunk film,

11 a leading edge of a shrinkable film,

12 a second longitudinal edge of a shrinkable film,

13 a trailing edge of a shrinkable film,

14 a seam,

15 a roll fed shrink film label,

16 a continuous tube of shrink sleeve labels,

18 a shrunk label,

20 an item,

22 a labelled item,

23 a neck of a bottle,

26 a bottom of a bottle,

28 a cap of the bottle.

A term “label” refers to a piece of material, which is used for labelling of an item. Label may be used to identify something. Label may be attached to an item. In other words, label is suitable to be applied to a surface of an item to provide decoration, and/or to display information about the product being sold, such as content information, a trade name, a logo, a barcode, or any other graphics. The item may be also called as an article, or a substrate. Preferably, the label comprises a plastic film and at least some graphics on at least one surface of the plastic film. A plastic film may also be referred to as a label film. The graphics may comprise, for example, printed information and/or decoration. The graphics, such as printing or other type of visual coatings, may be applied on the plastic film (either side) in a single process or via several successive steps. It is also possible that the visual coating include metallic foil or ink or similar.

Term “shrinkable” refers to a property of a film and a label made thereof to shrink under exposure to external energy, such as heat. Heat may be provided, for example in a steam tunnel. Shrinkable film is extruded and stretched (hot drawn) during manufacture and it remains its state after cooling down i.e. internal stresses provided during stretching are locked into the film. When this film is again brought up to the elevated temperature at which the stress was induced and then fixed during its manufacture, this stress is released and the film shrinks back. In other words, the film is shrunk by the internal stresses in a shrinkage process. Shrinkage process may include, for example, steam tunnel. Depending on the treatment applied, the film can be shrinkable both lengthwise and crosswise (film is called biaxially oriented), or mainly shrinkable in one direction (film is called uniaxially oriented).

“Heat shrink(able) film” or “heat shrink(able) label” refers to film and label having ability to shrink upon exposure to external energy, e.g. some level of heat. Heat shrink(able) film and heat shrink(able) label exhibit at least 15% preferably at least 25%, or at least 35% shrinkage between temperature of 65 and 98° C. Below 65° C. shrinkage is less than 15%. In an example, below 50° C. shrinkage is less than 10%. For example, shrinkage may between 0 and 15%, or between 1 and 10% below 65° C.

A heat shrink(able) label comprises or consists of a heat shrink(able) film and is suitable to be fitted around an article to be labelled and shrunk around the article. In addition, a heat shrink(able) label comprises at least some graphics on a surface of the heat shrink(able) film. A heat shrink(able) label may be a heat shrink sleeve label (HS) or a roll-fed shrink film label (RFS). Preferably, a heat shrink(able) label is roll-fed shrink film label, wherein the shrinkable film is uniaxially oriented in machine direction. A heat shrink(able) film without additional graphics, such as printing, may be used, for example, as a shrinking seal label, a tamper evident label or security label.

Term “printable surface” refers to a surface, such as a surface of a label film, that is suitable for printing. Printable surface is also able to maintain the printing, such as printed text and/or graphics. Printable surface has sufficiently high surface energy. A low surface energy may lead to poor retaining capability of printing ink applied to the surface. For example, a face film may have a surface energy at least 36 dynes/cm, preferably at least 38 dynes/cm, or at least 44 dynes/cm measured according to the standard ASTM D-2578. The surface tension may be between 36 and 60 dynes/cm, preferably between 38 and 56 dynes/cm, or between 44 and 50 dynes/cm. The surface tension level may also be maintained higher than or equal to 38 dynes/cm after 50 or 120 days. According to an embodiment, a printable film and a label produced thereof comprises at least one printable surface. Surface of the film may be printable as such. Alternatively, surface of the film may be treated prior to printing e.g. by corona unit at a printing line. For example, film may have lower surface energy than 36 dynes/cm, but the surface is suitable for surface treatment increasing the energy prior to printing.

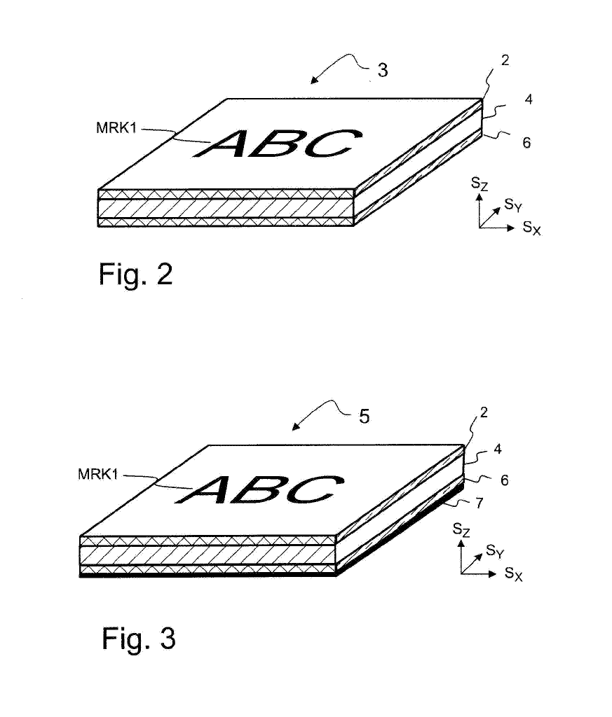

Term “machine direction” MD refers to the running direction Sₓ of the film or the label during film manufacturing or during labelling. “Transverse direction” TD or “cross direction” CD refers to the direction S_{y} perpendicular to the running direction Sₓ of the film. Directions are shown, for example, in FIG. 2.

“Transmittance” is a measure of light passing through the material, that is being transmitted through the material. The higher the amount of light that passes through, the larger the transmittance. Materials which do not transmit light at all or only transmit light in insignificantly small amounts are called opaque. Transmittance can be measured according to standard ASTM D1003.

Term “haze” refers to wide angle light scattering and a property used to describe transparency of a plastic film or a face stock of label consisting of the plastic film. Haze corresponds to the percentage of light transmitted through a film that is deflected from the original direction of the incoming light. Haze may be measured according to standard ASTM D1003. Haze may result as milky but sharp image. Term “clarity” refers to narrow angle scattering and may result as blurred but not milky image.

“Opacity” is a measure of impenetrability to electromagnetic radiation and typically it refers specifically to impenetrability of visible light wavelengths of the electromagnetic radiation. Opacity corresponds to a degree to which light (having certain wavelength range under investigation) is not allowed to travel through the material. Opacity may be measured according to standard according to the standard ISO 2471.

“Optical density” refers to a measure of the extent to which a substance transmits electromagnetic radiation with specific wavelength. The higher the optical density the lower the transmittance and the higher protection factor. Optical density may be measured at wavelength of 530 nm.

Terms “ultra-high temperature processing” and “ultra-heat treatment” (UHT), refer to sterilization of foodstuff by rapid temporal heating so as to kill spores, bacteria and other harmful microbes, for example in milk. Aseptically packaged UHT milk, if not opened, has shelf life of several months even at room temperature. However, packaging of milk is challenging due to the side effects of air, microbes and light. For example, ultraviolet (UV) light can alter the flavour of milk. This effect may be enhanced in the presence of other factors, for example, heat in the form of infrared radiation. Thus, containers e.g. plastic-coated paper cartons or laminated pouches are preferred for packaging of UHT milk. Also pigmented containers, such as pigmented plastic bottles may be used. However, the pigmented plastic bottles, such as pigmented polyethylene terephthalate (PET) bottles, are not able to be recycled.

Term “electromagnetic radiation blocking” refers to a capability of a material to cut electromagnetic radiation, such as visible light, ultraviolet light and/or infrared radiation (IR). For example, electromagnetic radiation wavelengths below 1 mm, preferably wavelengths below 750 nm, such as wavelengths of visible light and ultraviolet light.

Term “UV-blocking” refers to a capability of a material to cut ultraviolet (UV) light. Ultraviolet light is an electromagnetic radiation with wavelengths below 400 nm. UV radiation is present e.g. in sunlight and mercury-vapor lamps. Due to the high energy content (short wavelengths) UV light can cause e.g. chemical reactions and degradation (photo-oxidation) of a material. UV-blocking shrinkable film refers to a shrinkable film configured to block UV light. UV-blocking shrinkable label comprises or consists of the UV-blocking shrinkable film.

Term “visible light -blocking” refers to a capability of a material to cut visible light. Visible light is an electromagnetic radiation with wavelengths approximately between 400 nm and 750 nm. For example, mercury-vapor lamps produce ultraviolet light which becomes converted in the lamp shells into visible light using fluorescence. Intensive visible light may also cause photo-oxidation i.e. light induced oxidation. The intensity of all these effects, such as photo-oxidation and degradation, may be affected by dominant temperature which changes the rate of the chemical reaction(s).

Overlying/underlying refers to an arrangement of a layer in relation to another layer. Overlaying/underlying refers to an arrangement, where a layer partially or completely overlies/underlies another layer. The overlying/underlying layers are not necessarily in contact with each other, but one or more additional layers may be arranged between the overlying layers.

Adjacent refers to an arrangement, where a layer is next to another layer. Adjacent layers are in contact with each other and no additional layers are between the layers.

Topmost (outermost, uppermost, upmost) layer refers to a configuration of a label structure, where the topmost layer forms upper part of the label structure arranged opposite to the surface attaching the surface of an item when labelled. Topmost layer of a label may be, for example, a first skin layer, a print layer, a first layer, or a top coating (over-vanishing layer).

Undermost layer refers to a surface forming bottom part of the label structure arranged opposite to the topmost surface. Undermost layer is in contact with the surface of an article when labelled.

### Electromagnetic Radiation Blocking Label Arrangement

According to an embodiment an electromagnetic radiation blocking label arrangement comprises at least one label component including a shrinkable film and at least one metal deposition layer on the surface of the shrinkable film. The label component including a shrinkable film and at least one metal deposition layer may also be referred to as an electromagnetic radiation blocking shrinkable label.

The label arrangement may further comprise other label components, such as pressure sensitive label(s), shrinking seal label, and/or other shrinking labels separately arranged onto the surface of an item to be labelled. The other label components may be electromagnetic radiation blocking or non-blocking.

According to an embodiment an electromagnetic radiation blocking label arrangement consists of several shrinkable labels, wherein the shrinkable labels are arranged to block different wavelength ranges of the electromagnetic radiation.

### Electromagnetic Radiation Blocking Shrinkable Labels

Shrinkable labels, also referred to as shrink labels, are shrinking under exposure to external energy, such as elevated temperature. Shrinkable labels include both shrink sleeve labels and roll-fed shrink film labels. The shrinkable label may also be one of the following: tamper evident label, security label and shrinking seal label. Shrinkable labels comprise or consist of an oriented non-annealed plastic film, which is referred to as a shrinkable film. In order to provide electromagnetic radiation blocking, such as blocking of ultraviolet light, visible light blocking and/or infrared radiation, the plastic film comprises at least one of the following: light blocking agent, pigment, a metal deposition layer (metallization), and print layer suitable for blocking of electromagnetic radiation. Shrinkable labels blocking the ultraviolet light and/or visible light may be referred to as light blocking shrinkable labels.

Further, according to at least some/all embodiments, the metal deposited layer provides also a heat shielding effect preventing the content of the labelled container becoming heated due to the electromagnetic radiation effecting upon the container. The lower temperatures decelerate the chemical reactions and assist to prevent the other wavelengths of light possibly still penetrating through the label in small amounts to cause chemical degradation of the contents.

### Shrinkable Films

A shrinkable film may be drawn (stretched) in one direction. The film may be stretched in a machine direction. Alternatively, the film may be stretched in a transverse direction. The resulting film is thus monoaxially (uniaxially) oriented (MO). Monoaxially oriented film may be machine oriented (MDO) or transverse oriented (TDO) in accordance to the direction of the orientation (stretching). The oriented film is suitable for shrinking along the direction of orientation, during exposure to external energy. Shrinkage of the film is activated when the film is treated e.g. at elevated temperatures, such as passed through a hot air or steam-tunnel. Preferably, uniaxially oriented film has shrinking less than 10% or less than 5% in other directions (non-shrinking directions) of the film, during exposure to external energy. Expansion of the uniaxially oriented film is less than 5% in other directions (non-shrinking directions) of the film. Such a non-annealed film has not been specifically temperature treated to become a dimensionally stable, non-shrinking film.

A shrinkable film may be mono-axially (uniaxially) oriented. The shrinkable film of shrink sleeve label may be mono-axially oriented in transverse direction (TD). The shrinkable film of roll-fed shrink film label may be mono-axially oriented in machine direction (MD). According to an embodiment, the shrinkable label comprises or consists of a transverse direction oriented (TDO) film, which is non-annealed and therefore shrinkable in the orientation direction. According to another embodiment, the shrinkable comprises or consists of a machine direction oriented (MDO) film, which is non-annealed and therefore shrinkable in the orientation direction.

During stretching the randomly oriented polymer chains of the extruded films are oriented in the direction of stretching (drawing). Orientation under uniaxial stress provides orientation of polymer chains of the plastic film in the direction of stress provided. In other words, the polymer chains are oriented at least partially in the direction of stretching (drawing). In this application, machine direction (MD) refers to the running direction (Sₓ) of the film during manufacturing, as shown for example in FIG. 2. The degree of orientation of the polymer chains depends on the drawing ratio of the film. In other words, the polymer chains in the film stretched with a higher draw ratio are more oriented when compared to the films stretched with a lower draw ratio. The orientation, like orientation direction and ratio, may have effect on properties of the film, and/or the label comprising the film. The stretching of the film and orientation of the polymer chains may be observed microscopically. Further, the orientation is detectable e.g. from the mechanical properties of the films, such as values of modulus and/or tensile strength.

A ratio of total film thickness before and after stretching is called a “stretch ratio” or “draw ratio” (DR). It may also be referred to as an orientation ratio. In other words, stretch ratio is a ratio of non-oriented (undrawn) film thickness to the oriented (stretched) film thickness. The non-oriented film thickness is the thickness after extrusion and subsequent chilling of the film. When stretching the film, the thickness of the film may diminish in the same ratio as the film stretches or elongates. For example, a film having thickness of 100 micrometres before uniaxial orientation is stretched by a stretch ratio of 5. After the uniaxial orientation the film may have a fivefold diminished thickness of 20 micrometres. Thus, the stretch ratio (orientation ratio) of the film is 5.

A shrinkable film may have a monolayer structure. Alternatively, a shrinkable film may have a multilayer structure comprising two or more layers. A multilayer film may have a three layer structure comprising a first skin layer, a core layer and a second skin layer. Alternatively, a multilayer film may comprise five or even more layers. Preferably, a multilayer film includes a core layer and equal number of skin layers on both sides of the core layer. For example, a five layer structure comprises a core layer and two skin layers on both sides of the core. For example, a multilayer structure may comprise tie-layers. It is also possible that a multilayer structure includes several core layers.

Referring to FIG. 2, a plastic film of a shrinkable label may have a multilayer structure 3 comprising three layers. In a three layer structure, a core layer 4 is an intermediate layer. Skin layers 2,6 may be adjoined to the core layer 4. The first skin layer 2 and the second skin layer 6 may also be referred to as a front surface layer and a back surface layer, respectively. The front surface layer may be an outermost layer of the multilayer structure when labelled to a surface of an item. However, the front surface may further be over coated i.e. over-vanished. For example, in order to protect the printed graphics. In an example, the front surface layer comprises graphics (MRK1), such as printed information or decoration. Further, the surface layer(s) comprising graphics may be over-coated, for example over-vanished in order to protect the graphics.

Preferably a multilayer plastic film 3 has a symmetric structure. For example, symmetric three layer film comprises identical, or nearly identical skin layers 2,6 on opposite sides of the core layer 4. Symmetric structure may have effect on quality of the shrunk film and a shrunk label comprising said film. For example, wrinkles and curling of the label may be avoided.

Alternatively, a multilayer film 3 may be asymmetrical. For example, one skin layer may have more or less additives, e.g. anti-block or slip-agent, than the other skin layer. A film structure may also comprise additional layers, such as tie layers or protective layers. The multilayer film may also have asymmetry with respect to the skin layer thickness. In other words, there might be some thickness difference between the skin layers, for example in a three layer structure comprising two skin layers the skin layers may have different thickness. A multilayer film may be laminated or coextruded.

A core layer 4 may form major portion of the multilayer film structure 3. The core layer may be thicker than the first skin layer and the second skin layer. For example, the core may form from 40% to 80% or from 50% to 90% of the total thickness of the multilayer structure. Thickness of each skin layer may be from 5% to 25% of the total thickness of the multilayer structure. For example, each of the first skin layer and the second skin layer may form 10-30% or 5-25% of the total thickness of the multilayer structure. In an example, a three e layer film has a construction 10%/80%/10% for first skin/core/second skin, respectively. In an example, a three e layer film has a construction 5%/90%/5% for first skin/core/second skin, respectively. Thickness of the core layer may be from 10 to 50 microns, or from 20 to 40 microns. The thickness of a skin layer may be less than 15 microns, preferably around 10 or 7.5 microns or less. The overall thickness of the multilayer film may be from 20 to 70 microns or from 25 to 60 microns, preferably around 50 microns or around 40 microns or less.

Preferably a multilayer film has uniform overall thickness. Uniform thickness refers to a homogeneous thickness of the film, wherein a thickness variation along the film is small. For example in a film area of 100mm*100mm variation of the film thickness is less than 10%, preferably between 0.1 and 5.0%. Uniform thickness of the film provides better quality labels, for example, labels having good visual appearance. Uniform film thickness may have effect on the register control and image quality of the printing.

### Metallization Layer

According to an embodiment, a shrinkable film includes a metal deposition layer, also referred to as a metallization layer, so as to provide electromagnetic radiation blocking capability. The shrinkable film including a metallization layer may be referred to as metallised shrinkable film. Metallization layer may provide electromagnetic radiation blocking for the film. For example, metallization layer may provide blockage of visible light and ultraviolet light. Further it may provide blockage to infrared radiation. It may also provide reduced permeability of oxygen and water. The metal deposition layer may comprise or consist of aluminium (Al). For example, metallization layer may consist of pure aluminium i.e. 99.5% Al. Alternatively or in addition, it may include nickel or chromium. The metal deposition layer may contain only one metallic component, or it may include a combination of several metals deposited as separate layers or as a mixture. UV-light and visible light transmittance of the metallized film may be below 5%, for example between 0 and 5%, or between 0.1 and 5%.

The composition of the metal deposition layer may be selected according to the required wavelength blockage. Required wavelength blockage may be based on the sensitivity of the foodstuff or medicament packaged into the container. Typically, the metal deposition layer may be arranged to provide high blockage in the ultraviolet wavelength region below 400 nm, for example to protect UHT milk products from light-induced degradation. On the other hand, the metal deposition layer may be further designed to block and/or reflect infrared radiation at wavelengths longer than 1000 nm. This would have the effect of the sensitive contents of the container being not heated up during infrared/steam shrinkage of the label. Further, the metal deposition layer may be designed for blocking or letting through the visible wavelengths, for example 400-700 nm, or part of these wavelengths. It may be desirable that some individual label component of the label arrangement allows the customer to see the content of the container with certain limited wavelengths (colours) through the label.

The metal deposition layer may have an optical density of 1.0 to 3.5 in the selected wavelength range, for example in the ultraviolet and/or visible light wavelengths. For example, optical density of the metal deposition layer may be 2. In an example, optical density of the metal deposition layer is between 1.0 and 3.5 at wavelength of 530 nm. Thickness of the metal deposition layer may be between 30 and 500 Å (3 to 50 nm). Metal deposition layer has the benefit of avoiding the use of additional adhesive layer to bond the metal layer, such as Al-foil, to the label film. A layer of metal deposited directly on the film substrate has also the benefit of providing very thin films of exactly the desired thickness. This provides the cost benefit as well as possibility to tune the wavelength blockage behaviour of the film. If a separate laminated film would be used instead, the metal film would need to be thicker and the additional adhesive would also have an effect on the electromagnetic or light transmission of the label. Further, the metal deposited layer has positive effect on flexibility of the coated film. It allows the shrinkage of the film during labelling.

In an example, the metallization layer overlies the shrinkable film. For example, the metallization layer is provided on the first skin layer and thus it overlies the first skin layer of the multilayer shrinkable film.

In an example and referring to FIG. 3, the metallization layer 7 is provided on the second skin layer 6 of the multilayer shrinkable film and thus it underlies the multilayer shrinkable film.

It is also possible that there are metallization layers on both sides of the shrinkable film i.e. one metallization layer on a first skin layer 2 and another metallization layer on a second skin layer 6. Metallization layers may be of the same type, i.e. have same spectral transmittance or they may be of different type optimized to block different wavelength regions of the electromagnetic radiation.

In an example, the metallization layer may include several different layers of different metal materials to provide layers with tailored wavelength blocking capabilities.

The shrinkable film may include a primer layer, such as chemical coating, between the skin layer and the metallization layer. Alternatively, the metallization layer may be provided adjacent to the skin layer. However, the skin layer may be surface treated prior to metallization, for example by using corona or plasma treatment.

### Electromagnetic Radiation Blocking Shrinkable Label

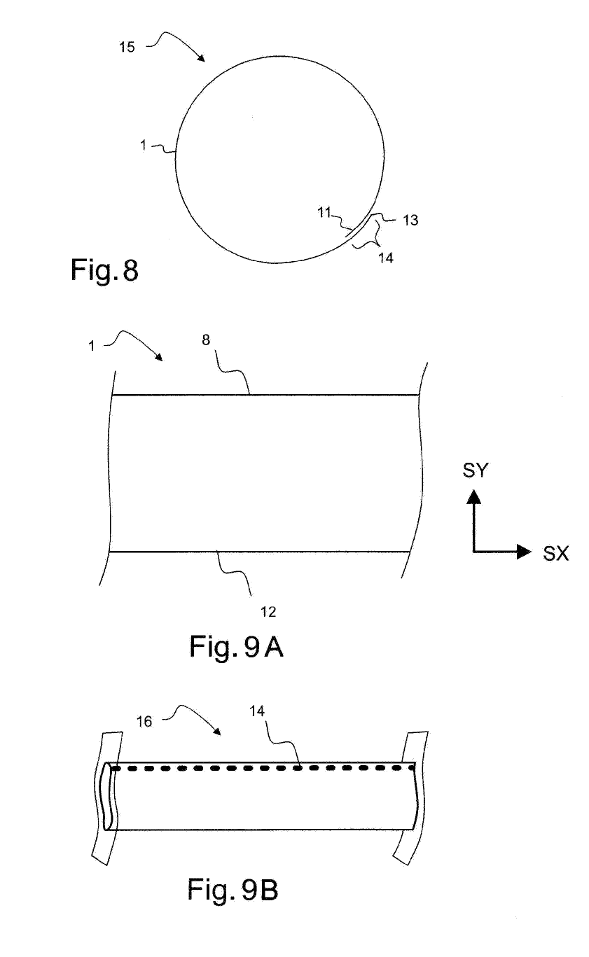

According to an embodiment, an electromagnetic radiation blocking shrinkable label, such as an electromagnetic radiation blocking heat shrink label, comprises or consists of a multilayer shrinkable film exhibiting electromagnetic radiation blocking capability. Referring to FIG. 3, an electromagnetic radiation blocking shrinkable film 5 includes a multilayer plastic film comprising a first skin layer 2, a core layer 4, a second skin layer 6 and a metallization layer 7 on the second skin layer. Alternatively or in addition, the core layer 4 of a multilayer plastic film may include light blocking agent or pigment suitable for absorbing electromagnetic radiation, such as UV and/or visible light. In addition, the electromagnetic radiation-blocking shrink label may comprise at least some graphics on a surface of the film, e.g. on the first skin layer. The graphics may be a print layer providing electromagnetic radiation blocking effect, such as UV- and/or visible light blocking effect. In addition, the shrink label may comprise an adhesive. The adhesive may be applied in a joint area, also referred to a seam area, of cylindrical label, wherein the opposite edges of the label film are overlapping. For example, the adhesive may be applied between the overlapping edges. Referring to FIG. 8, an adhesive may be applied between a trailing edge 13 and a leading edge 11 of a shrinkable film 1. When rolling the film 1 over itself, the trailing and leading edges overlap and form a seam 14. Alternatively, seaming may be provided by hot-seaming with a hot bar. In addition, adhesive (e.g. hot melt adhesive) may be used to hold the label film on the surface of the item to be labelled. The adhesive may be applied on the label film or on the item in an area between the leading edge and the surface of the item.

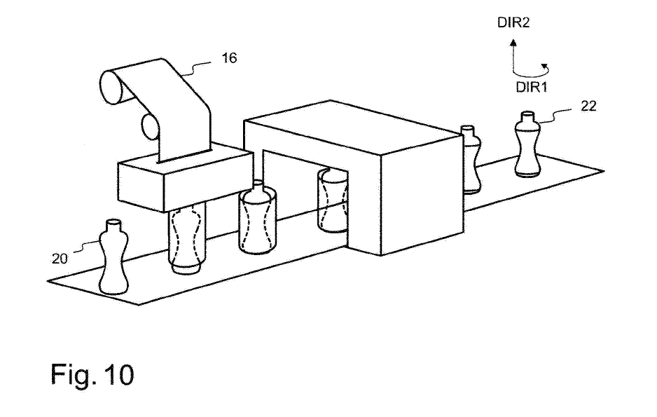

According to an embodiment, an electromagnetic radiation blocking shrinkable label is a shrink sleeve label, such as a heat shrink sleeve label. The shrink sleeve label is in a form of tubular sleeve comprising a shrinkable film 1 which is oriented uniaxially in a transverse direction (S_{y}). Referring to FIGS. 9A and 9B, a shrink sleeve label 16 is formed by seaming a first longitudinal edge 8 and a second longitudinal edge 12 of the film 1 extending parallel to a machine direction of the face film (Sₓ). In other words, the film is rolled around the axis extending in the machine direction (Sₓ) of the film and the seam 14 is formed between the overlapping longitudinal edges 8,12 of the film 1. Seaming may be provided, for example, by hot-seaming with a hot bar. Such a preformed continuous sleeve tube 16 may be further rolled into a roll and provided for separate labelling process, as shown in FIG. 10.

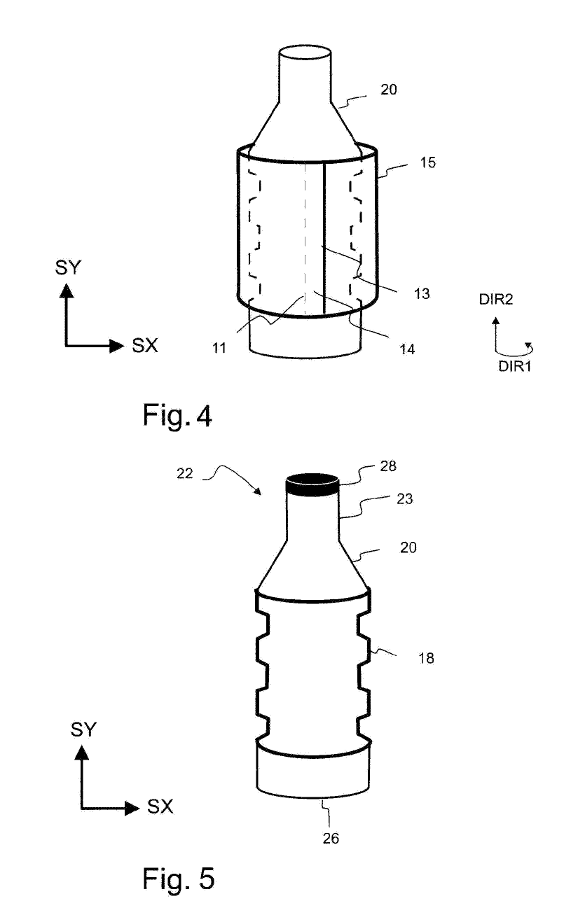

According to another embodiment, an electromagnetic radiation blocking shrink label is a roll-fed shrink film label comprising a shrinkable film 1 which is oriented uniaxially in a machine direction (Sₓ). Referring to FIG. 4 a roll fed shrink film label 15 is formed on-line around an article to be labelled or around a mandrel by seaming a leading edge 11 and a trailing edge 13 of the film. Preferably, the shrink film label is formed around a mandrel. In other words, the shrinkable film is rolled around the axis extending in the transverse direction (S_{y}) of the film. A label comprises a seam 14 between the overlapping leading edge 11 and trailing edge 13 of the film. The seam extends perpendicular to the uniaxial orientation direction of the film. If the label is formed around a mandrel it is further transferred to an article to be labelled. Again, typically the film 1 has been provided its visual appearance and information during earlier converting steps. The shrink film label 15 is able to shrink in the direction DIR 1 during application of external energy, such as heat. DIR 1 corresponds to the uniaxial orientation direction of the shrink film. FIG. 5 shows a shrunk label 18 around an item 20.

### Materials for Shrinkable Films and Electromagnetic Radiation Blocking Shrinkable Labels Produced Thereof

The shrinkable film may comprise propylene terpolymer or propylene random copolymer. In addition the shrinkable film may comprise modifiers, for example, polyolefin elastomer (OE), polyolefin plastomer (OP) and/or olefin block copolymer (OBC). Polyolefin elastomer and polyolefin plastomer may also be referred to as olefinic elastomer and olefinic plastomer, correspondingly. Further, the shrinkable film may comprise cyclic olefin copolymer(s). In addition, the shrinkable film comprises at least one of the following: light blocking agent, pigment, a metal deposition layer (metallization) so as to provide blocking of electromagnetic radiation.

In order to improve e.g. manufacturing of the film, the shrinkable film may further comprise additives, such as plasticizer, lubricant, antistatic agent, slip additive, anti-blocking agent. Still further additives may be used e.g. cavitating agent and antioxidant.

Propylene terpolymer(s) may be used for a core and/or skin layer(s) of a multilayer film structure and labels produced thereof. Propylene terpolymer(s) refers to copolymer(s) comprising three distinct monomers, of which one is propylene. Other monomers may be ethylene, 1-butene, 1-hexene or 1-octene. Propylene terpolymer may be at least one of the following terpolymers comprising propylene: 1-butene/propylene/ethylene, propylene/ethylene/1-hexene and propylene/ethylene/1-butene. 1-butene/propylene/ethylene terpolymer may comprise more 1-butene monomer units when compared to the propylene/ethylene/1-butene.

Propylene terpolymer(s) may have density 0.90 g/cm³, when measured according to standard ISO 1183. Melt flow rate may be between 0.9 and 7.5 or between 4.5 and 6.5 g/10 min, when measured according to standard ISO 1133 at 230 degrees 0/2.16 kg. Melting temperature may be between 127 and 137 degrees C. (ISO 11357-3).

In an example, propylene terpolymer comprises density of 0.90 g/cm³, when measured according to standard ISO 1183. Melt flow rate may be 5.5 g/10 min, when measured according to standard ISO 1133 at 230 degrees C./2.16 kg. Melting temperature may be 137 degrees C. (ISO 11357-3).

In an example, propylene terpolymer comprises density of 0.90 g/cm³, when measured according to standard ISO 1183. Melt flow rate may be 6 g/10 min, when measured according to standard ISO 1133 at 230 degrees C./2.16 kg. Melting temperature may be 132 degrees C. (ISO 11357-3).

In an example, propylene terpolymer comprises density of 0.90 g/cm³, when measured according to standard ISO 1183. Melt flow rate may be 5.5 g/10 min, when measured according to standard ISO 1133 at 230 degrees C./2.16 kg. Melting temperature may be 132 degrees C. (ISO 11357-3).

In an example, propylene terpolymer comprises density of 0.90 g/cm³, when measured according to standard ISO 1183. Melt flow rate may be 0.9 g/10 min, when measured according to standard ISO 1133 at 230 degrees C./2.16 kg. Melting temperature may be 132 degrees C. (ISO 11357-3).

In an example, propylene terpolymer comprises density of 0.90 g/cm³, when measured according to standard ISO 1183. Melt flow rate may be 7.5 g/10 min, when measured according to standard ISO 1133 at 230 degrees C./2.16 kg. Melting temperature may be 132 degrees C. (ISO 11357-3).

In an example, propylene terpolymer comprises density of 0.90 g/cm³, when measured according to standard ISO 1183. Melt flow rate may be 5.5 g/10 min, when measured according to standard ISO 1133 at 230 degrees C./2.16 kg. Melting temperature may be 127 degrees C. (ISO 11357-3).

In an example, propylene terpolymer comprises density of 0.90 g/cm³, when measured according to standard ISO 1183. Melt flow rate may be 5.5 g/10 min, when measured according to standard ISO 1133 at 230 degrees C./2.16 kg. Melting temperature may be 128 degrees C. (ISO 11357-3).

In an example, propylene terpolymer comprises density of 0.90 g/cm³, when measured according to standard ISO 1183. Melt flow rate may be 5.5 g/10 min, when measured according to standard ISO 1133 at 230 degrees C./2.16 kg. Melting temperature may be 130 degrees C. (ISO 11357-3).

Random copolymer of propylene (also referred to as propylene random copolymer) may be used for a core layer and/or for skin layer(s) of multilayer film structures and labels. Propylene random copolymer may be propylene-ethylene copolymer or propylene-butylene copolymer. Random copolymer of propylene with ethene may have density between 0.89 and 0.91 g/cm³. Melt flow rate may be between 1.5 and 11 g/10 min.

In an example, random copolymer of propylene with ethene may have density of 0.9 g/cm³, when measured according to standard ISO 1183. Melt flow rate MFR (at 230° C./2.16 kg) may be 1.7 g/10 min, when measured according to ISO 1133.

In an example, random copolymer of propylene with ethene may have density of 0.9 g/cm³, when measured according to standard ISO 1183. Melt flow rate MFR (at 230° C./2.16 kg) may be 2.2 g/10 min, when measured according to ISO 1133. Vicat softening temperature may be 122° C., when measured according to standard ISO 306 (A50 (50° C./h 10N)).

In an example, random copolymer of propylene with butylene may have density of 0.9 g/cm³, when measured according to standard ISO 1183. Melt flow rate MFR (at 230° C./2.16 kg) may be 10 g/10 min, when measured according to ISO 1133. Vicat softening temperature may be 130° C., when measured according to standard ISO 306 (A50 (50° C./h 10N)).

Following cyclic polymers: cyclic olefin polymer (COP), cyclic block copolymer (CBC), cyclic olefin copolymer (COC) may be used both for the skin and core layers.

Cyclic olefin polymer may be produced by ring-opening metathesis polymerization of single type of cyclic monomers followed by hydrogenation. According to an example, melt index of a cyclic olefin polymer, also referred to as cyclo-olefin polymer, may be between 11 and 25 g/10 min at 230° C., for example between 15 and 25 g/10 min, or between 11 and 17 g/10 min.

Cyclic block copolymer is a polymer comprising two or more chemically distinct regions or segments, referred to as blocks. Blocks may be joined in a linear manner. Cyclic block copolymer may comprise blocks of hydrogenated polystyrene, polycyclohexylethylene (PCHE), and ethylene-butene (EB). Alternatively it may comprise blocks of polycyclohexylethylene (PCHE) and ethylene-propylene (EP). Specific gravity of cyclic block copolymer may be between 0.928 and 0.938 kg/dm³. Melt flow rate may be 3 g/10 min at 300° C./1.2 kg, or 15 g/10 min at 280° C./2.16 kg or 76 g/10 min at 250° C./2.16 kg.

Cyclic olefin copolymer contains polymerized units derived from at least one cyclic and at least one acyclic olefin. COCs may be produced by chain copolymerization of cyclic monomers with ethene. The cyclic olefin may comprise at least 4 carbon atoms and a unsaturated site for coordinated polymerization with the acyclic olefin. The cyclic olefin may comprise an unsubstituted or substituted ring. The acyclic olefin may be an alpha olefin having two or more carbon atoms. Cyclic olefin copolymers may be based on cyclic monomers, such as norbornene and/or tetracyclododecene. Cyclic monomer(s) may be chain copolymerized with ethene (ethylene). For example, cyclic olefin copolymer may be comprise monomers of norbornene and ethene. Alternatively, cyclic olefin copolymer may comprise monomers of tetracyclododecene and ethene. Cyclic olefin copolymer may also consists of monomers of norbornene, tetracyclododecene and ethene. Alternatively, cyclic olefin monomer may be at least one of the following: cyclobutene, cyclopentene, cyclooctene, 5-methylnorbornene, 3-methylnorbornene, ethylnorbornene, phenylnorbornene, dimethylnorbornene, diethylnorbornene, dicyclopentadiene, methyltetracyclododecene, 6-methylnorbornene, 6-ethylnorbornene, 6-n-butylnorbornene, 5-propylnorbornene, 1-methylnorbornene, 7-methylnorbornene, 5,6-dimethylnorbornene, 5-phenylnorbornene, 5-benzylicnorbornene, 8-methyltetracyclo-3-dodecene, 8-ethyltetracyclo-3-dodecene, 8-hexyltetracyclo-3-dodecene, 2,10-dimethyltetracyclo-3-dodecene and 5,10-dimethyltetracyclo-3-dodecene. In an example, cyclic olefin copolymer may be norbornene copolymerized with ethene. It may have norbornene content between 61 and 63 wt. %.

For example, skin layer(s) may comprise cyclic olefin copolymer having density of 980 kg/m³, when measured according to standard ISO 1183. COC may have linear and amorphous structure. Melt volume rate may be 4 cm³/10 min, when measured according to standard ISO 1133 at 230° C. with test load of 2.16 kg. Glass transition temperature may be 33 degrees C., when measured according to standard ISO 11357.

For example, skin layer(s) may comprise cyclic olefin copolymer having density of 1.02 g/cm³, when measured according to standard ASTM D792. Melt volume rate may be 15 g/10 min, when measured according to standard ASTM D1238 at 260° C. with test load of 2.16 kg. Glass transition temperature may be 70 degrees C.

For example, cyclic olefin copolymer may have melt flow rate 6.0 cm³/10 min, when tested according to standard ISO 1133 at 230° C. with test load of 2.16 kg. Density may be 1010 kg/m3, when measured according to standard ISO 1183. Glass transition temperature may be 65° C., when measured according to standard ISO 11357-1, -2,-3 with heating rate of 10° C./min.

For example, cyclic olefin copolymer may have melt flow rate 12 cm³/10 min, when tested according to standard ISO 1133 at 230° C. with test load of 2.16 kg. Density may be 1010 kg/m3, when measured according to standard ISO 1183. Glass transition temperature may be 78° C., when measured according to standard ISO 11357-1, -2,-3 with heating rate of 10° C./min.

Cyclic polymers, such as cyclic olefin copolymers may have effect on the shrinking behaviour of the film. For example, a specific shrinkage curve may be achieved. A cyclic olefin copolymer in the core layer may have effect on achieving good adhesion between the core layer with skin layer(s) including cyclic olefin copolymers. In addition, the cyclic olefin copolymer contained in the core layer may have effect of increasing the overall shrinkage of the film.

Cyclic olefin copolymers, cyclic block copolymers, and cyclic olefin polymers may also have effect on clarity of the shrinkable film and label produced thereof.

The skin layer(s) may comprise acyclic olefin polymer(s), such as polyethylene (PE). Polyethylene may be at least one of the following: low density polyethylene (LDPE), medium density polyethylene (MDPE), and linear low density polyethylene (LLDPE). Melt flow rate of polyethylene(s) may be between 0.5 and 4.5 g/10 min, when measured at 190° C./2.16 kg.

Linear low density polyethylene (LLDPE) refers to random copolymer of ethylene and longer chain alpha-olefins, such as butene, hexene or octene, provided by using either Ziegler-Natta catalyst or metallocene catalyst. Density of the LLDPE may be between 0.916 and 0.940 g/cm³. In an example, LLDPE may be Ziegler-Natta catalyst based. For example, LLDPE may be a copolymer of ethylene and 1-octene. Density of LLDPE may be 0.916 g/cm³, when measured according to standard ASTM D792. Alternatively, metallocene-catalysed LLDPE may be used. For example, ethylene-hexene copolymer having density of 0.918 g/cm³.

According to an embodiment, skin layer(s) comprise linear low density polyethylene (LLDPE). LLDPE may be Ziegler-Natta catalyst based. For example, LLDPE may be a copolymer of ethylene and 1-octene. Density of LLDPE may be 0.916 g/cm³, when measured according to standard ASTM D792. Melt Index may be 2.0 g/10 min, when measured according to standard ASTM D1238 at 190° C./2.16 kg. Alternatively, metallocene-catalysed LLDPE may be used. For example, ethylene-hexene copolymer. Density of metallocene-catalysed LLDPE may be 0.918 g/cm³ and melt index 2.0 g/10 min, when measured according to standard ASTM D1238 at 190° C./2.16 kg. For example, LLDPE has density 0.935 g/cm³, when measured according to standard ASTM D1505. Melt index may be 2.6 g/10 min, when measured at 190° C./2.16 kg according to standard ASTM D1238.

For example, LLDPE has density 0.917 g/cm³, when measured according to standard ASTM D792. Melt index may be 2.3 g/10 min, when measured at 190° C./2.16 kg according to standard ISO 1133.

For example, polyethylene has density 0.916 g/cm³, when measured according to standard ASTM D792. Melt index may be 4 g/10 min, when measured at 190° C./2.16 kg according to standard ISO 1133.

For example, LLDPE is a copolymer of an ethylene and 1-octene having density 0.916 g/cm³, when measured according to standard ASTM D792. Melt index may be 2.0 g/10 min, when measured at 190° C./2.16 kg according to standard ISO 1133.

For example, metallocene based LLDPE with hexene as comonomer has density 0.917 g/cm³, when measured according to standard ISO 1183. Melt index (melt flow rate) may be 1.0 g/10 min, when measured at 190° C./2.16 kg according to standard ISO 1133.

For example, metallocene based polyethylene with hexene as comonomer has density 0.934 g/cm³, when measured according to standard ISO 1183. Melt index (melt flow rate) may be 3.1 g/10 min, when measured at 190° C./2.16 kg according to standard ISO 1133.

For example, polyethylene is metallocene catalysed ethylene-hexene copolymer having density 0.918 g/cm³, when measured according to standard ISO 1183. Melt index (melt flow rate) may be 2.0 g/10 min, when measured at 190° C./2.16 kg according to standard ISO 1133. Alternatively, melt index may be 2.0 g/10 min, when measured according to standard ASTM D1238 at 190° C./2.16 kg. Alternatively, melt index may be 3.5 g/10 min, when measured according to standard ASTM D1238 at 190° C./2.16 kg.

LLDPE may have effect on visual appearance of the film. It may have effect on reducing and/or avoiding the finger marking tendency of the film. LLDPE may further have an effect on providing good interlayer attachment for multilayer films. Also MDPE and LDPE may have effect on reducing and/or avoiding the finger marking tendency of the film. They may also have effect on interlayer adhesion of the multilayer face film.

A core and/or skin layer(s) of a multilayer film may further include at least one of the following modifiers: olefinic elastomer, olefinic plastomer and ethylene-octene block copolymer(s). For example, the shrinkable film may comprise ethylene elastomer(s), propylene elastomer(s), propylene plastomer(s), ethylene-octene block copolymer(s), or any mixture thereof.

In an example, a core and/or skin layer(s) may comprise at least one of the following modifiers: propylene/ethylene plastomer, ethylene/octene elastomer, ethylene/butene elastomer, and ethylene-octene block copolymer.

Propylene elastomer(s) and propylene plastomer(s) may be propylene-ethylene copolymers produced with a special catalyst and technology. A plastomer is a polymer that softens when heated. It hardens when cooled, but remains flexible. An elastomer is elastic polymer resembling natural rubber, returning to its original shape after being stretched or compressed. Propylene plastomers and propylene elastomers have narrow molecular weight distribution (MWD), broad crystallinity distribution and wide melt range.

Ethylene-octene block copolymers may have density between 0.866 and 0.887 g/cm³, when measured according to ASTM D792. Melt index may be between 1 and 5 g/10 min, when measured according to ASTM D1238 (at 2.16 kg, 190° C.). DSC melting temperature may be between 119 and 122° C.

In an example, ethylene-octene block copolymer may have density of 0.877 g/cm³, when measured according to ASTM D792. Melt index may be 5 g/10 min, when measured according to ASTM D1238 (at 2.16 kg, 190° C.). DSC melting temperature may be 122° C.

In an example, ethylene-octene block copolymer may have density of 0.866 g/cm³, when measured according to ASTM D792. Melt index may be 1 g/10 min, when measured according to ASTM D1238 (at 2.16 kg, 190° C.). DSC melting temperature may be 121° C.

In an example, ethylene-octene block copolymer may have density of 0.887 g/cm³, when measured according to ASTM D792. Melt index may be 5 g/10 min, when measured according to ASTM D1238 (at 2.16 kg, 190° C.). DSC melting temperature may be 119° C.

In an example, ethylene-octene block copolymer may have density of 0.866 g/cm³, when measured according to ASTM D792. Melt index may be 5 g/10 min, when measured according to ASTM D1238 (at 2.16 kg, 190° C.). DSC melting temperature may be 119° C.

Ethylene-butene elastomer(s) may have density between 0.862 and 0.880 g/cm³, when measured according to ASTM D792. Melt index may be between 0.8 and 5 g/10 min, when measured according to ASTM 1238 (at 2.16 kg, 190° C.). Mooney viscosity may be between 7 and 24 MU, when measured according to standard ASTM 1646 (ML 1+4 at 121° C.). Total crystallinity may be between 12 and 19%. DSC melting peak may be between 34 and 76° C., when measured at heating rate of 10° C./min. Glass transition temperature may be may be −58 and −42° C. (DSC inflection point).

In an example, ethylene-butene elastomer may have density 0.862 g/cm³, when measured according to ASTM D792. Melt index may be 1.2 g/10 min, when measured according to ASTM 1238 (at 2.16 kg, 190° C.). Mooney viscosity may be 19 MU, when measured according to standard ASTM 1646 (ML 1+4 at 121 ° C.). Total crystallinity may be 12%. DSC melting peak may be 34° C., when measured at heating rate of 10° C./min. Glass transition temperature may be may be −58° C. (DSC inflection point).

In an example, ethylene-butene elastomer may have density 0.862 g/cm³, when measured according to ASTM D792. Melt index may be 3.6 g/10 min, when measured according to ASTM 1238 (at 2.16 kg, 190° C.). Mooney viscosity may be 9 MU, when measured according to standard ASTM 1646 (ML 1+4 at 121° C.). Total crystallinity may be 12%. DSC melting peak may be 40° C., when measured at heating rate of 10° C./min. Glass transition temperature may be may be −56° C. (DSC inflection point).

In an example, ethylene-butene elastomer may have density 0.865 g/cm³, when measured according to ASTM D792. Melt index may be 5 g/10 min, when measured according to ASTM 1238 (at 2.16 kg, 190° C.). Mooney viscosity may be 7 MU, when measured according to standard ASTM 1646 (ML 1+4 at 121° C.). Total crystallinity may be 13%. DSC melting peak may be 35° C., when measured at heating rate of 10° C./min. Glass transition temperature may be may be −53° C. (DSC inflection point).

In an example, ethylene-butene elastomer may have density 0.880 g/cm³, when measured according to ASTM D792. Melt index may be 0.8 g/10 min, when measured according to ASTM 1238 (at 2.16 kg, 190° C.). Mooney viscosity may be 24 MU, when measured according to standard ASTM 1646 (ML 1+4 at 121° C.). Total crystallinity may be 19%. DSC melting peak may be 64° C., when measured at heating rate of 10° C./min. Glass transition temperature may be may be −44° C. (DSC inflection point).

Ethylene-octene elastomer(s) may have density between 0.857 and 0.908 g/cm³, when measured according to ASTM D792. Melt index may be between 0.5 and 18 g/10 min, when measured according to ASTM 1238 (at 2.16 kg, 190° C.). Mooney viscosity may be between 3 and 33 MU, when measured according to standard ASTM 1646 (ML 1+4 at 121° C.). Total crystallinity may be between 13 and 34%. DSC melting peak may be 38 and 104° C., when measured at heating rate of 10° C./min. Glass transition temperature may be may be −58 and −31° C. (DSC inflection point).

In an example, ethylene-octene elastomer may have density 0.857 g/cm³, when measured according to ASTM D792. Melt index may be 1 g/10 min, when measured according to ASTM 1238 (at 2.16 kg, 190° C.). Mooney viscosity may be 25 MU, when measured according to standard ASTM 1646 (ML 1+4 at 121° C.). Total crystallinity may be 13%. DSC melting peak may be 38° C., when measured at heating rate of 10° C./min. Glass transition temperature may be may be −58° C. (DSC inflection point).

In an example, ethylene-octene elastomer may have density 0.863 g/cm³, when measured according to ASTM D792. Melt index may be 0.5 g/10 min, when measured according to ASTM 1238 (at 2.16 kg, 190° C.). Mooney viscosity may be 33 MU, when measured according to standard ASTM 1646 (ML 1+4 at 121° C.). Total crystallinity may be 16%. DSC melting peak may be 56° C., when measured at heating rate of 10° C./min. Glass transition temperature may be may be −55° C. (DSC inflection point).

In an example, ethylene-octene elastomer may have density 0.870 g/cm³, when measured according to ASTM D792. Melt index may be 5 g/10 min, when measured according to ASTM 1238 (at 2.16 kg, 190° C.). Mooney viscosity may be 8 MU, when measured according to standard ASTM 1646 (ML 1+4 at 121° C.). Total crystallinity may be 19%. DSC melting peak may be 59° C., when measured at heating rate of 10° C./min. Glass transition temperature may be may be −53° C. (DSC inflection point).

In an example, ethylene-octene elastomer may have density 0.880 g/cm³, when measured according to ASTM D792. Melt index may be 18 g/10 min, when measured according to ASTM 1238 (at 2.16 kg, 190° C.). Mooney viscosity may be 3 MU, when measured according to standard ASTM 1646 (ML 1+4 at 121° C.). Total crystallinity may be 24%. DSC melting peak may be 76° C., when measured at heating rate of 10° C./min. Glass transition temperature may be may be −50° C. (DSC inflection point).

The modifier(s) of olefinic elastomers/plastomers may have density between 0.863 and 0.888 g/cm³, when measured according to standard ASTM D 792. Melt index may be between 1.1 and 9.1 g/10 min, when measured according to standard ASTM D 1238 at 190 degrees 0/2.16 kg.

In an example, propylene-ethylene copolymer plastomer/elastomer comprises density between 0.863 and 0.888 g/cm³, when measured according to standard ASTM D 792. Melt flow rate may be between 2 and 8 dg/min, when measured according to standard ASTM D 1238 at 230 degrees C., 2.16 kg. Total crystallinity may be between 14 and 44%. Glass transition temperature may be between −33 and −17 degrees C.

In an example, olefinic elastomer is produced by using metallocene catalyst technology and the ethylene content being 11 wt. %. Density may be 0.873 g/cm³, when measured according to standard ASTM D1501. Melt flow rate may be between 8 g/10 min. Melt index may be 3.6 g/10 min, when measured according to standard ASTM D 1238 at 190 degrees C., 2.16 kg.

In an example, olefinic elastomer comprises isotactic propylene repeat units with random ethylene distribution and the ethylene content being 11 wt. %. Density may be 0.874 g/cm³, when measured according to standard ASTM D1501. Melt flow rate may be between 3 g/10 min. Melt index may be 1.1 g/10 min, when measured according to standard ASTM D 1238 at 190 degrees C., 2.16 kg.

In an example, olefinic elastomer is produced by using metallocene catalyst technology and the ethylene content being 15 wt. %. Density may be 0.863 g/cm³, when measured according to standard ASTM D1501. Melt flow rate may be between 20 g/10 min. Melt index may be 9.1 g/10 min, when measured according to standard ASTM D 1238 at 190 degrees C., 2.16 kg.

In an example, olefinic plastomer is propylene/ethylene plastomer exhibiting density 0.876 g/cm³, when measured according to standard ASTM D729. Melt flow rate may be between 8.0 g/10 min, when measured at 230 degrees C./2.16 kg according to standard ASTM D1238. Vicat softening temperature may be 59 degrees C., when measured according to standard ASTM D1525.

In an example, olefinic plastomer is propylene/ethylene plastomer exhibiting density 0.891 g/cm³, when measured according to standard ASTM D729. Melt flow rate may be between 8.0 g/10 min, when measured at 230 degrees C./2.16 kg according to standard ASTM D1238. Vicat softening temperature may be 105 degrees C., when measured according to standard ASTM D1525.

In an example, olefinic plastomer is propylene/ethylene plastomer exhibiting density 0.876 g/cm³, when measured according to standard ASTM D729. Melt flow rate may be between 2.0 g/10 min, when measured at 230 degrees C./2.16 kg according to standard ASTM D1238. Vicat softening temperature may be 63 degrees C., when measured according to standard ASTM D1525.

In an example, olefinic plastomer is propylene/ethylene plastomer exhibiting density 0.888 g/cm³, when measured according to standard ASTM D729. Melt flow rate may be between 2.0 g/10 min, when measured at 230 degrees C./2.16 kg according to standard ASTM D1238. Vicat softening temperature may be 94 degrees C., when measured according to standard ASTM D1525

Modifiers, such as olefinic elastomer(s) and/or olefinic plastomer(s), may have a positive effect on the ability of the film to be stretched (oriented) and thus on the shrinkage potential of the film.

In order to modify the appearance and/or properties shrinkable films may also include e.g. pigment and/or light blocker (also referred to as blocking agent or light blocking agent). Light blockers are ingredients able to absorb electromagnetic radiation, such as visible and UV light so as to reduce chemical reactions and photo-oxidation of a material caused by the radiation. Blockers include inorganic blockers e.g. titanium dioxide, zinc oxide. Alternatively the light blocker may be organic chemical absorber, such as indole, benzotriazole, benzophenone, cyanoacrylate or salycilate. The amount of light blocker may be between 0.1 and 30 wt. %, if any. For example, in a three layer structure of shrinkable film, the core layer may include the light blocker.

Alternatively or in addition, the film may include pigment, such as titanium dioxide (TiO₂). For example rutile TiO₂ or anatase TiO₂. Alternatively or in addition other white pigments may be used. In an example, antimony oxide, zinc oxide. Pigment may have effect on absorbing UV and visible light. It may further have effect on whiteness and opacity of the film. TiO₂ has effect on providing opacity by scattering light. The amount of pigment may be between 0.1 and 30 wt. %. In a multilayer structure preferably the core layer includes the pigment(s).

### Examples of Shrinkable Films

According to an embodiment a shrinkable film has a three layer structure comprising following layers: a first skin layer 2, a core layer 4, a second skin layer 6. The layers may have different compositions. For example, skin layer(s) of the multilayer face film may have different composition when compared to the composition of the core layer. Also first and second skin layers may have different compositions. Alternatively, the first and second skin layers may have similar compositions.

### Core Layer

In an example, a core layer 4 includes following components: propylene terpolymer and/or propylene random copolymer; and at least one of the following modifiers: olefinic elastomer (OE), olefinic plastomer (OP) and olefin block copolymer (OBC). Olefin block copolymer may be one of the ethylene-octene block copolymers presented above. Olefinic elastomer may be one of the olefinic elastomers presented above, e.g. ethylene/octene elastomer, ethylene/butene elastomer. Olefinic plastomer may be propylene plastomer e.g. propylene/ethylene plastomer. In addition, the core layer may further include cyclic olefin copolymer(s) (COC).

According to a first example, a total amount of propylene terpolymer(s) may be between 35 and 80 wt. %. In an example, the core layer may comprise different grades of propylene terpolymers, such as terpolymers having different melt flow rates. Examples of propylene terpolymers are presented above.

According to a second example, a total amount of propylene random copolymer(s) may be between 35 and 80 wt. %. Examples of propylene random copolymer(s) are presented above.

According a third example, the core layer comprises both propylene terpolymer(s) and propylene random copolymer(s). Total amount of said polymers being between 35 and 80 wt. %.

A total amount of modifier(s) may be between 20 and 40 wt. %. An amount of cyclic olefin copolymer(s), if any, may be at most 10 wt. %.

In an example, the core layer may include pigment and/or light blocking agent as disclosed above.

### Skin Layers

According to a first example, the first skin layer and the second skin layer include cyclic olefin copolymers (COC); and polyethylene (PE), such as linear low density polyethylene (LLDPE), medium density polyethylene (MDPE) and/or low density polyethylene (LDPE). Instead or in addition to cyclic olefin copolymers the core layer may comprise other cyclic polymers, such as cyclic block copolymer (CBC) or cyclic olefin polymer (COP). For example, in a three layer film, both a first skin layer and a second skin layer contain at least two of the following cyclic polymers: cyclic olefin copolymer, cyclic block copolymer, and cyclic olefin polymer. The film may comprise cyclic olefin copolymers having different glass transition temperatures. In an example, the film comprises first cyclic olefin copolymer COC₁ and second cyclic olefin copolymer COC₂ having different glass transition temperatures (T_{g}). In an example, shrinkable film may comprise at least two cyclic olefin copolymers comprising different glass transition temperatures in range of 30-100° C. and the difference between the glass transition temperatures being between 5 and 60° C. Glass transition temperature may be measured according to standard ISO 11357.

Further, the skin layers may comprise modifiers, such as olefinic elastomer, olefinic plastomer or olefin block copolymer; and/or propylene terpolymer. In addition the skin layers may comprise minor amount of additives e.g. antiblocking agent.

Total amount of cyclic olefin polymers may be between 50 and 95 wt. %, or between 60 and 90 wt. %. Total amount of polyethylene(s), e.g. LLDPE and/or LDPE may be between 5 and 20 wt. %. Total amount of olefinic elastomer, olefinic plastomer or olefin block copolymer; and/or propylene terpolymer may be at most 20 wt. %. An amount of additives may be between 0.5 and 2 wt. %. Examples of the components are provided above.

According to a second example, the first skin layer and the second skin layer include propylene terpolymer(s). In an example, skin layers may comprise different grades of propylene terpolymers, such as terpolymers having different melt flow rates. Examples of propylene terpolymers are presented above. Total amount of terpolymer(s) may be 98 wt. %.

According to a third example, the first skin layer and the second skin layer include random copolymer(s) of propylene. Examples of random copolymer(s) of propylene are presented above. Total amount of random copolymer(s) of propylene may be 98 wt. %.

According to a fourth example, the first skin layer and the second skin layer include random copolymer(s) of propylene and propylene terpolymer(s). Examples of random copolymer(s) of propylene and propylene terpolymer(s) are presented above. Total amount of random copolymer(s) of propylene and propylene terpolymer(s) may be 98 wt. %. For example, the skin layers may comprise between 0.5 and 49 wt. % of random copolymer(s) of propylene and between 49 and 97.5 wt. % of propylene terpolymer(s). Alternatively, the skin layers may comprise between 0.5 and 49 wt. % of propylene terpolymer(s) and between 49 and 97.5 wt. % of random copolymer(s) of propylene.

### Manufacturing

### Manufacturing a Shrinkable Film

Non-oriented film may be manufactured by using either a cast or blown-film extrusion process. A shrinkable film may be obtained by stretching (drawing) the extruded film to an extent several times its original dimension to orient the film. Stretching may also be designated as orienting. Extruded film may be stretched uniaxially in transverse direction (across the film). Alternatively, the film may be stretched uniaxially in machine direction (lengthwise).

The film of the shrink label may be drawn (stretched) in one direction. The film may be drawn in a machine direction or in a transverse direction. The resulting film is thus monoaxially (uniaxially) oriented (MO). Monoaxially oriented film may be machine oriented (MDO) or transverse oriented (TDO) in accordance to the direction of the orientation (stretching). Monoaxial orientation ratio may be between 2 and 10, preferably between 4 and 8. Preferably, a film is oriented uniaxially in machine direction.

The stretching in TD may be performed by heating the continuous film web and stretching it in transverse direction on a tenter frame. The stretching may be performed below the melting temperature of the polymer and/or at or near the glass transition temperature of the polymer. Preferably the film stretching temperature is between 50 and 130° C. The stretching in MD may be performed by means of a machine direction orienter via rolls with increasing speed. The stretching occurs due to a difference in speed between the last and the first rolls. In a stretching process the rolls are heated sufficiently to bring the substrate to a suitable temperature, which is normally below the melting temperature (Tₘ), or around the glass transition temperature (T_{g}) of the polymer. In an example, orientation process temperature is between 50 and 130° C.

After uniaxial stretching (orienting), the film is not heat set, i.e. not annealed, in order to provide shrinkage for the film. After stretching at elevated temperature the film is immediately cooled by passing the film through cooling rolls. Cooling of the film may be gradual. Cooling may be performed with one or more cooling rolls having decreasing temperature profile starting at or just below stretching temperature and decreasing gradually to around room temperature. Cooling is performed in steps and the cooling roll temperatures may be selected between 20 and 80° C. Stretching and subsequent cooling may provide suitable shrink potential for the film. Due to the shrink potential, the oriented films are able to shrink under elevated temperature towards the non-oriented state of the film. In an example, subsequent application of heat causes the oriented film to relax and the oriented film may return towards or substantially back to its original unstretched dimensions. Thus, the oriented films primarily shrink in the orientation direction.

The uniaxially stretched and subsequently cooled films are referred to non-annealed films having shrinkage potential and ability to shrink when external energy is provided to the film. In other words, non-annealed film refers to a film which is not relaxed to become temperature stable. Non-annealed film has shrinkage potential, when e.g. temperature exceeds a certain limit. Respectively annealed film refers to film which is relaxed to have better temperature stability, for example, within a certain temperature range defined by the annealing temperature.

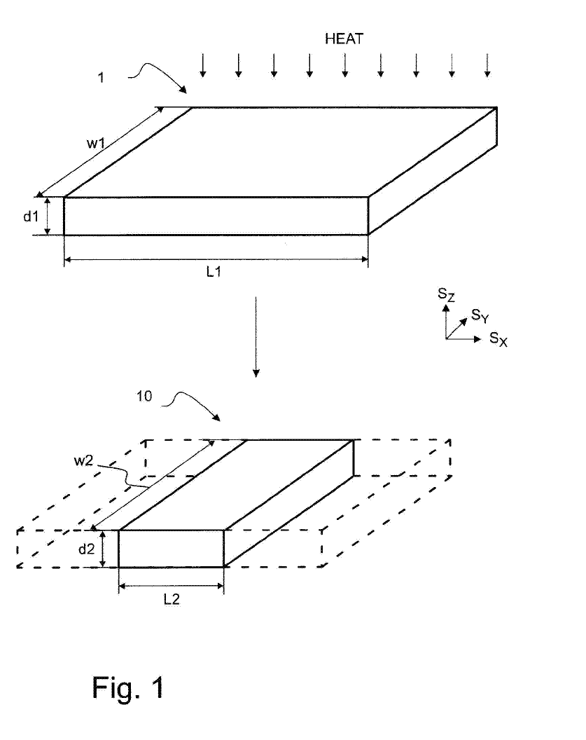

Referring to FIG. 1, not heat set (non-annealed), uniaxially oriented shrinkable film 1 having dimensions of length L1, width w1 and thickness d1, is arranged to shrink under application of heat so as to form a shrunk film 10. Uniaxial orientation direction Sₓ, of the film is parallel to the film length L1 and L2. Uniaxial orientation direction may be, for example, transverse direction TD.

Alternatively, uniaxial orientation direction may be machine direction MD. The corresponding film dimensions are length L2, width w2 and thickness d2 after shrinking. Under heating the uniaxially oriented film 1 is capable of shrinking in the direction of the orientation Sₓ. In other words, the length of the film reduces, when heating is applied, i.e. L1>L2. If the film is oriented only in one direction Sₓ, in the perpendicular direction S_{y}, the dimension w1 is substantially equal to w2 after heat treatment. Same applies to the labels comprising uniaxially oriented shrinkable film.

Temperature of the orientation process may have effect on the degree of shrinkage of the film and shrink label comprising said film. For example, orientation process temperature in range of 50 to 130 degrees C. may provide at least 10%, or at least 15%, preferably at least 25%, or at least 35% shrinkage of the face film between subsequent heating with temperature in range of 65 and 98° C. At 50° C. shrinkage is below 10%.

Before, during, or after the stretching the film may be subjected to corona discharge treatment or plasma treatment so as to improve the bonding properties of the film against a metal deposition layer. Alternatively, the film may be chemically treated prior to metallization.

Forming a metal deposition layer on the surface of the shrinkable film may include physical deposition method, such as a vacuum deposition method, a sputtering method or an ion plating method. Alternatively, the metal deposition layer may be provided by a chemical deposition method, such as a chemical vapor deposition (CVD) method.

The metal deposition layer may contain only one metallic component, or it may be tailored from a combination of several metals which again may be deposited as separate layers. The selection of the composition of the metal deposition layer is made according to the spectral blocking capabilities required from the layer. In other words, the blocking may be tailored to happen in the ultraviolet wavelengths (for example <400 nm), and/or in the visible wavelengths (for example 400-700 nm), and/or in the infrared wavelength region (for example >700 nm). For a certain type of foodstuff, the label could be opaque in the ultraviolet wavelengths and also heat shielding in the infrared wavelengths, but still at least partially transparent in the visible wavelengths.

The shrinkable film, may further be printed in order to provide visual effect and/or to display information. Printing may be performed by using traditional printing processes, for example, flexographic, gravure offset, and digital printing methods, such as liquid-toner, dry-toner or ink-jet processes. A multilayer film may comprise printing on a surface of a first skin layer. The graphics, such as printing or other type of visual coatings, may be applied in a single process or via several printing or coating steps. It is also possible that the visual coating include metallic foil or ink or similar. Printing is usually subsequently over-varnished. A shrinkable label being one of the following: tamper evident label, security label and shirking seal label may be un-printed, pigmented or they may comprise printing.

The shrinkable film surface may be treated prior to printing. The print receiving surface may be treated by flame treatment, corona treatment, or plasma treatment in order to increase the surface tension of the surface and to enhance, for example, adhesion of the printed graphics. A low surface tension may lead to poor retaining capability of printing ink applied to the surface.

The shrinkable film may also be treated after printing. Such treatment may include, for example, over-varnishing or other coating methods to provide protection to the printing and/or adding other properties or enhanced visual effects in addition to the information print.

### Manufacturing a Shrinkable Label and Labelling

A shrinkable film may be used for providing shrinkable labels, also referred to as shrink labels or shrinking labels. The shrink labels are suitable for labelling of a wide range of product designs and particularly suitable for highly contoured containers and products comprising curved sections, recesses and/or protrusions at their outer surface. Shrinkage properties of films and labels enable labelling of highly contoured items. The item may comprise or consists of polyethylene terephthalate (PET). The item may have a shape of a bottle. Shrinkable label may form at least one label component of the label arrangement.

Shrinkable labels are shrinking under exposure to external energy, such as elevated temperature. Shrink labels are referred to more particularly as heat shrink labels when shrinkable under exposure of elevated temperature i.e. heat. Shrinkable labels include both shrink sleeve labels and roll-fed shrink film labels. The shrinkable label may also be one of the following: tamper evident label, security label and shrinking seal label. The label may be a full body label, i.e. the label may cover the whole outer surface of the item labelled. Alternatively, the label may cover the item only partially. For example, a cap of the bottle may be covered with a shrinking seal label.

“Roll-fed shrink film label” (RFS) refers to a label, which is applied in an labelling process, where a ready cut face film is rolled over a container or a mandrel so as to form an individual label, which is subsequently shrunk around an article to be labelled under exposure to external energy, such as elevated temperature. Under exposure to the external energy the label is able to conform shape and size of the article. A roll-fed shrink film label comprises or consists of a shrinkable face film. The face film may be a monolayer or multilayer film. In addition, the label comprises at least some graphics on a surface of the face film.

“Shrink sleeve label” also referred to as “a shrink sleeve label” or to as “a shrinkable sleeve label” refers to a label in the form of tubular sleeve 16. Individual labels may be cut from the continuous tubular sleeve and fitted around an article to be labelled and shrunk around the article under exposure to external energy, such as elevated temperature. Tubular sleeve is made from a shrink face film by seaming. A shrink sleeve label comprises or consists of a shrinkable face film. The face film may be a monolayer or multilayer film. In addition, the shrink sleeve label comprises at least some graphics on a surface of the face film.

The roll-fed shrink film labelling process may be called as on-line labelling process. Roll-fed shrink films may be uniaxially oriented in machine direction (MD). When a label consists of a MDO shrink film as a face layer, and the machine direction of the face layer extends circumferentially around the item, the label is arranged to shrink primarily in the orientation direction under exposure to external energy, e.g. when heated. Subsequent shrinking process at high temperatures enables tight fitting of the label around the item. Heat shrinking may occur at a shrink tunnel, where for example hot air may be blown towards passing items. Alternatively shrinkage may be provided by hot steam, infrared radiation, or the like, or any combination of the above methods. Preferably, the shrinkage is carried out in a steam tunnel.

Referring to FIG. 10, “shrink-sleeve labelling” or “heat shrinkable sleeve film labelling” refers to a labelling process, where a preformed label tube (or sleeve) is introduced around an item. Shrink sleeve label comprises or consists of transverse direction oriented (TDO) shrink film. The film is seamed into a continuous tube label around the axis extending to the machine direction (Sₓ). Seaming may be provide e.g. by using hot-seaming with the hot bar or adhesive. The formed continuous tube (or sleeve) 16 is cut into predetermined lengths and supplied as a form of individual tube label around an item 20. The item or container may be warmed before a cylindrical tube label is introduced over it. Tube around an item is heated in order to shrink the tube label around the item so as to form a labelled item 22. The transverse direction orientation of the tube label extends circumferentially around the item. Thus, the label primarily shrinks in the transverse direction.

According to an embodiment, a method for providing a shrink label and subsequent labelling of an item may comprise at least the following steps:
providing a multilayer film comprising a first skin layer, a core layer and a second skin layer;
stretching the multilayer film uniaxially in machine direction at temperature between 50 and 130° C. so as to provide uniaxially in MD oriented multilayer film;
cooling the uniaxially oriented multilayer film so as to provide shrink potential in the uniaxial stretching direction;
metallizing at least one of the first skin layer and the second skin layer of the multilayer film;
providing a continuous MD oriented multilayer film to a roll, unrolling and printing the film;
cutting the printed film into desired length of a label;
wrapping the cut multilayer film (the label comprising desired length) around a cylindrical mandrel;
seaming the seam area so as to provide the shrink label;
replacing the label from the cylindrical mandrel around an item to be labelled;
applying external energy providing shrinking of the label so as to fit the label tightly around the item so as to form a labelled item comprising shrunk label.

Cooling may be gradual and performed in steps comprising temperatures between 20 and 80° C. Seaming may include e.g. hot-seaming with a hot bar. Applying external energy may comprise heating the shrink label at temperature between 65 and 140° C. so as to form a tight fitting label around the item.

Alternatively, seaming may be provided by using adhesive, such as UV-acrylic hot-melt adhesive or hot-melt adhesive based on block copolymers. Alternatively seam may be formed by solvent seaming, laser-welding or ultrasonic radiation.

According to an embodiment, a method for providing a shrink label and subsequent labelling of an item may comprise at least the following steps:
providing a multilayer film comprising a first skin layer, a core layer and a second skin layer;
stretching the multilayer film uniaxially in transverse direction at temperature between 50 and 130° C. so as to provide uniaxially in TD oriented multilayer film;
cooling the uniaxially oriented multilayer film so as to provide shrink potential in the uniaxial stretching direction;
metallizing at least one of the first skin layer and the second skin layer of the multilayer film;
printing the film;
seaming the film into a form of a continuous tube;
cutting the continuous tube into desired length of a sleeve label;
providing the sleeve label around an item;
applying external energy providing shrinking of the label so as to fit the label tightly around the item so as to form a labelled item comprising shrunk label.

Seaming may be provided using hot-seaming with a hot bar, adhesive, such as UV-acrylic hot-melt adhesive or hot-melt adhesive based on block copolymers, solvent seaming, laser-welding or ultrasonic radiation.

### Labelled Item and Recycling

According to an embodiment an item comprises a shrunk electromagnetic radiation blocking label. The item may be a polyethylene terephthalate (PET) bottle. The bottle may be clear. The item to be labelled may be highly contoured container, such as a bottle, having e.g. recesses and/or protrusions at the outer surface. Thus, for example, a diameter of the bottle may alternate. The bottle may comprise different diameters. Difference between the diameters to be labelled in a bottle may be up to 30%, or up to 20%, or 2-30%, or 5-20%, or 8-15%. According to an example, the difference between the smallest diameter and the largest diameter of the item to be labelled may be up to 30%, or up to 40%, or up to 50%, or up to 60%, or up to 70%, or 2-70%, or 5-60%, or 10-35%.

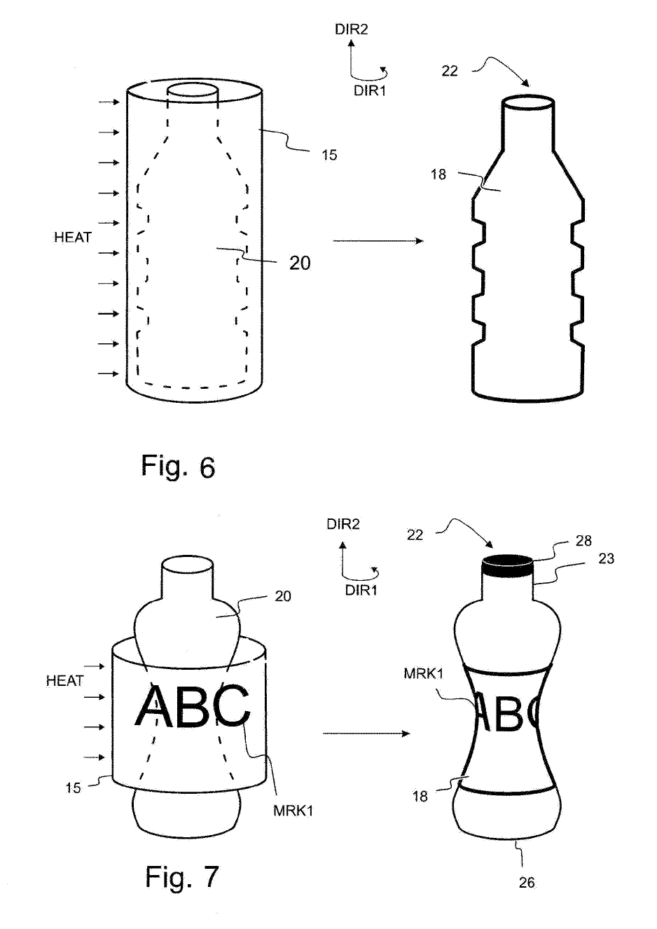

The label may be full body label, i.e. the shrunk label may cover at least 90% of the outer surface of the item labelled. For example, a cap 28 of the bottle may remain non-labelled. Referring to FIG. 6 a shrink label 15 may be a full body label, i.e. the shrunk label 18 may cover substantially the whole outer surface of the item 20. Alternatively, the label 15,16 may cover the item only partially, as shown in FIGS. 5 and 7. Referring to FIG. 7, for example a neck 23 of a bottle may remain non-labelled, or a separate and/or different label may be used for the bottle neck part than for the bottle volume part. Further a bottom 26 of the bottle may comprise a separate label, for example a pressure sensitive label.

According to an embodiment, in order to cover the whole surface area of the container or at least most of its surface area, the electromagnetic radiation blocking label arrangement may be provided. The label arrangement may be composed of several separate label components which can be separately or successively arranged onto the container to obtain preferably up to 90-100% coverage of the total surface area of the container. These label components may all be attached using shrinkage. Alternatively, all or some of them may be attached using adhesives, for example pressure sensitive adhesives. It is also possible that a label component may be attached both using adhesives and shrinking. All of these label components, in combination, would then provide the necessary level of blockage of the electromagnetic radiation.

As one example of such arrangement of separate label components to provide a full coverage blocking label structure could be a bottle, where the bottom of the bottle 26 (outer surface of the base of the bottle) is first covered with a flat adhesive label (first label component) or with a cup style adhesive label extending a short distance up along the sides of the bottle. The label used for the bottom may be round or having another shape corresponding to the shape of the bottom of the bottle. This bottom labelling may take place before or after filling of the container. Then, the sides of the bottle are labelled with a shrink sleeve type label (second label component) which may extend on or over the cap 28 of the bottle. Alternatively, the upper neck of the bottle and the cap area may be covered with yet another label (third label component) attached with shrinking and/or adhesive. After this the bottle is covered 100% with electromagnetic radiation blocking label arrangement comprising several separate label components to provide a full coverage blocking (shielding) label structure.

In an example, the item, such as a bottle, comprises a label arrangement including at least one label component being electromagnetic radiation blocking shrinkable label. Other label components of the arrangement, if any, may be blocking or non-blocking.

The item may also be recyclable, such as clear PET bottle. At the time of recycling the PET bottle, a label attached to the PET bottle, is separated and removed.

After the item comprising a label or a label arrangement has been used, the item is crushed (grinded) into pieces. In particular, when the area in between the label and the surface of the item is free from adhesive, the film may be separated from the item during this crushing. After crushing the pieces of the labelled item may be take into washing step comprising a heated washing liquid comprising caustic soda. Temperature of the liquid may be around 80° C. In a preferred embodiment, the pieces of the item are separated from the pieces of the label based on the difference in their densities. For example, the label may float on a liquid (washing liquid) having a special density. The item may sunk in the liquid. In an embodiment,
the item has a first density D1,
the label has a second density D2, and
the ratio of the second density to the first density, D2/D1, at most 0.9; preferably at most 0.8 or at most 0.7 at a temperature, such as at the temperature 80° C.

Thereby, when the liquid has a special density that is more than D2 and less than D1, the pieces of the item sink into the liquid, while the pieces of the label float on the liquid. At 80° C., the density of water is 972 kg/m³. However, the density of the cleaning liquid can be affected by ingredients (e.g. salts) added to the cleaning liquid. Thus, in a preferred embodiment, the second density D2 (of the label) is less than 1000 kg/m³, preferably less than 950 kg/m³at the temperature 80° C. Moreover, preferably in addition, the first density D1 (of the item) is more than 1000 kg/m³ at the temperature 80° C.

For example, in an item comprising PET (having the density of about 1380 kg/m³), and a label having the density of about 920 kg/m³, the ratio is as low as 0.67.

In an embodiment, the thermally shrinkable face film (and the shrunk film of the item) has a density D2 of less than 1100 kg/m³, preferably less than 1000 kg/m³, such as less than 920 kg/m³. The densities are typically measured near room temperature, such as 25° C., however, increasing temperature up to e.g. 80° C. does not affect the density much.

### Properties

Shrinkable labels according to least some/all embodiments have effect on providing controlled shrinkage, i.e. specific amount of shrinkage at specific temperature range. For example good shrinkage at the steam-tunnel operating temperatures. At least some/all shrinkable labels have shrinkage at least 15%, preferably at least 25%, or at least 35% above 65 degrees C. in the maximum shrinkage direction (in the orientation direction). At 50° C. shrinkage may be less than 10%, or less than 5%. In an example, shrinkage in the orientation direction of the shrinkable film may be between 25 and 65% at a temperature range 65-98° C. The shrinkable films and labels produced thereof may have effect on providing good quality labelling and shrunk labels comprising reduced amounts of defects, such as wrinkles or insufficient shrinkage at the necks of the bottles.

In an example, shrinkage may be measured according to the following method: providing a sample with measured and marked 100 mm*100 mm area, placing the sample for 15 seconds to the water baths having temperatures at intervals of 5° C. from 55° C. to 98° C., cooling the sample at water bath having temperature of around room temperature, drying the sample and measuring the dimensions of the marked area of the sample. Preferably at least 3 or more parallel samples are used. Shrinkage is determined as the relative change of dimensions. The term “shrinkage” is defined with reference to the method; however, it is evident, and has been noticed, that the same shrinkage properties apply regardless of the method, provided that the same temperatures are used. I.e. the composition of heat transfer medium (air, steam, water) is not critical for shrinkage behaviour.

Shrinkable labels according to least some/all embodiments have effect on providing improved stiffness. Shrinkable label arrangement may also provide improved mechanical properties for the labelled container.

Shrinkable labels according to least some/all embodiments have effect on providing more economical labels. They may also provide more economic electromagnetic radiation blocking effect for containers, for example blocking against photodegradation.

Shrinkable labels according to least some/all embodiments have effect on providing easy separation of the shrunk labels during subsequent recycling process. In addition they may allow efficient and cost effective recycling of the containers, such as clear PET bottles.

At least some/all embodiments have effect on printability of the shrinkable film. The shrinkable label film may have effect on enabling high printing quality. According to some/all embodiments the shrinkable film has excellent ink adhesion and register control, allowing for example gravure printing. Wetting surface tension of the print receiving skin layer may be higher than or equal to 38 mN/m, for example 44 mN/m, when measured according to standard ISO 8296. For example, the print receiving skin layer may have a surface energy at least 36 dynes/cm, preferably at least 38 dynes/cm or at least 42 dynes/cm measured according to the standard ASTM D-2578. The surface energy may be between 36 and 60 dynes/cm, preferably between 38 and 56 dynes/cm or between 42 and 50 dynes/cm. Surface energy expressed in units of dynes/cm meaning force/unit length may also be expressed in units of mN/m.

Shrinkable labels according to least some/all embodiments have density between 0.85 and 0.98 g/cm³ at room temperature (23±2° C.). The density may be measured according to standard EN ISO 1183, Gravimetric density of solid and liquid materials.

According to at least some/all embodiments, the shrinkable labels comprising metallization may have an opacity of at least 70%, or at least 75%, or at least 80% when measured according to the standard ISO 2471. Opacity may be 70-95%, or preferably 70-90%.

According to at least some/all embodiments, the shrinkable labels comprising metallization may exhibit light transmittance between 0 and 20% at wave lengths below 1mm, or below 750 nm, or below 620 nm. In an example between 200 and 650 nm the light transmittance may be less than 20%, preferably less than 10%.

According to at least some/all embodiments, the shrinkable film comprising metallization may have a light transmittance of 0.01 to 5% at wave lengths between 200 and 620 nm, between 200 and 450 nm, or between 420 and 520 nm.

According to at least some/all embodiments, the shrinkable labels comprising metallization has effect on blocking UV light, visible light and infrared radiation. The shrinkable labels comprising metallization may have effect on providing not only protection against photodegradation (light-oxidation) but also providing heat shielding. In an example, blocking of the electromagnetic radiation in a wide wavelength range may provide enhanced protection against detrimental degradation and flavour defects of the product packaged into the container comprising the shrinkable label with metallization. In an example, IR blocking capability of the film may have effect on temperature of the product packaged, i.e. the temperature of the product may not rise, thus preventing or slowing down the degradation of the product.

The label arrangement may comprise only one label component, which is attachable using shrinkage. Alternatively, the label arrangement may be further supplemented with additional label component(s) that are attached to the container, for example, with pressure sensitive adhesive. Such label arrangements may provide the full blocking (shielding) label structure, which may cover 100% of the outer surface area of the container. Such full coverage may not be needed in all applications, and for example 60-80%, or 80-90% coverage of the total area of the container may be sufficient. The other parts of the container, for example, the thicker bottom and/or the cap may provide their own blocking (shielding) effects without additional labelling.

Similarly, the label arrangements do not need to provide 100% electromagnetic radiation blockage in the given wavelength, but depending on the sensitivity of the foodstuff or other packed material, it may be sufficient to provide only 50-80%, or perhaps 80% or above blockage of the radiation, for example blockage of the ultraviolet radiation. The level of sufficient protection may depend on the required shelf life of the products packaged as well as the other environmental circumstances during the logistics of the product.

The label arrangements of the at least some/all embodiments may have effect on providing protective packaging of sensitive compositions, such as foodstuff or medicament, and preventing the contents of the container from being deteriorated by the light, such as UV and/or visible light. In an example, the clear PET bottles comprising metallized shrinkable labels enable retaining the quality of the dairy products, such as UHT milk packaged into the bottle. The metallized label arrangements may have effect on reducing the photodegradation of the milk that can produce quality defects e.g. negative flavours and reduced nutritional value, such as degradation of vitamins.

In the following numbered examples 1.1.-1.23 are provided:

### EXAMPLE 1.1

An electromagnetic radiation blocking label arrangement comprising at least one label component including:
a shrinkable film;
at least one metal deposition layer on a surface of the shrinkable film, and wherein the shrinkable film is uniaxially stretched so as to form shrinking capability for the shrinkable film in the uniaxial stretching direction when exposed to an external energy.

### EXAMPLE 1.2

An electromagnetic radiation blocking label arrangement according to example 1.1, wherein the shrinkable film comprises: propylene terpolymer or propylene random copolymer and at least one of the following modifiers: polyolefin elastomer, polyolefin plastomer and olefin block copolymer.

### EXAMPLE 1.3

An electromagnetic radiation blocking label arrangement according to example 1.1 or 1.2, wherein the at least one metal deposition layer comprises at least one of the following: aluminium, chromium and nickel.

### EXAMPLE 1.4

An electromagnetic radiation blocking label arrangement according to any of the previous examples, wherein the at least one metal deposition layer consists of aluminium.

### EXAMPLE 1.5

An electromagnetic radiation blocking label arrangement according to any of the previous examples, wherein the at least one metal deposition layer has thickness between 30 and 500 Å.

### EXAMPLE 1.6

An electromagnetic radiation blocking label arrangement according to any of the previous examples, wherein the shrinkable film comprises layers in the following order: a first skin layer, a core layer, and a second skin layer and wherein the at least one metal deposition layer is underlying the second skin layer.

### EXAMPLE 1.7

An electromagnetic radiation blocking label arrangement according to any of the previous examples, wherein the core layer comprises light blocking agent or pigment between 0.1 and 30 wt. %.

### EXAMPLE 1.8

An electromagnetic radiation blocking label arrangement according to any of the previous examples, wherein the at least one label component exhibits density between 0.85 and 0.98 g/cm³ at room temperature (23±2° C.).

### EXAMPLE 1.9

An electromagnetic radiation blocking label arrangement according to any of the previous examples, wherein the at least one label component exhibits an opacity between 70 and 95%, when measured according to standard ISO 2471.

### EXAMPLE 1.10

An electromagnetic radiation blocking label arrangement according to any of the previous examples, wherein the at least one label component exhibits a light transmittance between 0 and 20% at wavelengths between 200 and 650 nm.

### EXAMPLE 1.11

An electromagnetic radiation blocking label arrangement according to any of the previous examples, wherein the at least one label component exhibits an optical density between 1.0 and 3.5 at wavelength of 530 nm.

### EXAMPLE 1.12

An electromagnetic radiation blocking label arrangement according to any of the previous examples, wherein the at least one label component exhibits at least 15% shrinkage in the uniaxial stretching direction between temperature of 65 and 98° C.

### EXAMPLE 1.13

An electromagnetic radiation blocking label arrangement according to any of the previous examples, wherein the label arrangement further comprises a second label component, wherein the second label component is self-adhesive label or shrink label.

### EXAMPLE 1.14

Use of an electromagnetic radiation blocking label arrangement according to any of the examples 1.1-1.13 for labelling of a foodstuff container.

### EXAMPLE 1.15

Use of an electromagnetic radiation blocking shrinkable label according to example 1.14, wherein the foodstuff is dairy product.

### EXAMPLE 1.16

Use of an electromagnetic radiation blocking shrinkable label according to example 1.14, wherein the foodstuff is UHT milk.

### EXAMPLE 1.17

A labelled item comprising an electromagnetic radiation blocking label arrangement according to any of the examples 1.1-1.13, wherein the at least one label component is shrunk around the item.

### EXAMPLE 1.18

A labelled item according to example 1.17, wherein the item comprises the second label component arranged onto the bottom of the item or around the neck of the item.

### EXAMPLE 1.19

A labelled item according to example 1.18, wherein the item is clear polyethylene terephthalate container.

### EXAMPLE 1.20

A labelled item according to any of the examples 1.17 to 1.19, wherein the item is a bottle for packaging of dairy product.

### EXAMPLE 1.21

A labelled item according to any of the examples 1.17 to 1.19, wherein the item is a bottle for packaging of UHT milk.

### EXAMPLE 1.22

A labelled item according to claim any of the examples 1.17 to 1.19, wherein the labelled item contains dairy product, for example UHT milk.

### EXAMPLE 1.23

A labelled item according to any of the examples 1.17 to 1.22, wherein the label arrangement covers at least 90% of the outer surface of the labelled item.

1. An electromagnetic radiation blocking label arrangement comprising at least one label component including:
a shrinkable film;
at least one metal deposition layer on a surface of the shrinkable film, and wherein the shrinkable film is uniaxially stretched so as to form shrinking capability for the shrinkable film in the uniaxial stretching direction when exposed to an external energy.

2. An electromagnetic radiation blocking label arrangement according to claim 1, wherein the shrinkable film comprises: propylene terpolymer or propylene random copolymer and at least one of the following modifiers: polyolefin elastomer, polyolefin plastomer and olefin block copolymer.

3. An electromagnetic radiation blocking label arrangement according to claim 1, wherein the at least one metal deposition layer comprises at least one of the following: aluminium, chromium and nickel.

4. An electromagnetic radiation blocking label arrangement according to claim 1, wherein the at least one metal deposition layer consists of aluminium.

5. An electromagnetic radiation blocking label arrangement according to claim 1, wherein the at least one metal deposition layer has thickness between 30 and 500 Å.

6. An electromagnetic radiation blocking label arrangement according to claim 1, wherein the shrinkable film comprises layers in the following order: a first skin layer, a core layer, and a second skin layer and wherein the at least one metal deposition layer is underlying the second skin layer.

7. An electromagnetic radiation blocking label arrangement according to claim 1, wherein the core layer comprises light blocking agent or pigment between 0.1 and 30 wt. %.

8. An electromagnetic radiation blocking label arrangement according to claim 1, wherein the at least one label component exhibits density between 0.85 and 0.98 g/cm³ at room temperature (23±2° C.).

9. An electromagnetic radiation blocking label arrangement according to claim 1, wherein the at least one label component exhibits an opacity between 70 and 95%, when measured according to standard ISO 2471.

10. An electromagnetic radiation blocking label arrangement according to claim 1, wherein the at least one label component exhibits a light transmittance between 0 and 20% at wavelengths between 200 and 650 nm.

11. An electromagnetic radiation blocking label arrangement according to claim 1, wherein the at least one label component exhibits an optical density between 1.0 and 3.5 at wavelength of 530 nm.

12. An electromagnetic radiation blocking label arrangement according to claim 1, wherein the at least one label component exhibits at least 15% shrinkage in the uniaxial stretching direction between temperature of 65 and 98° C.

13. An electromagnetic radiation blocking label arrangement according to claim 1, wherein the label arrangement further comprises a second label component, wherein the second label component is self-adhesive label or shrink label.

14.-16. (canceled)

17. A labelled item comprising an electromagnetic radiation blocking label arrangement according to claim 1, wherein the at least one label component is shrunk around the item.

18. A labelled item according to claim 17, wherein the item comprises the second label component arranged onto the bottom of the item or around the neck of the item.

19. A labelled item according to claim 18, wherein the item is clear polyethylene terephthalate container.

20. A labelled item according to claim 17, wherein the item is a bottle for packaging of dairy product.

21. A labelled item according to claim 17, wherein the item is a bottle for packaging of UHT milk.

22. A labelled item according to claim 17, wherein the labelled item contains UHT milk.

23. A labelled item according to claim 17, wherein the label arrangement covers at least 90% of the outer surface of the labelled item.
